(19) United States
(12) Patent Application Publication
(10) Pub. No.: US 2015/0136585 A1
(43) Pub. Date: May 21, 2015

(54) METHOD FOR SPUTTERING FOR PROCESSES WITH A PRE-STABILIZED PLASMA

(71) Applicant: John Douglas Busch, San Jose, CA (US)

(72) Inventor: John Douglas Busch, San Jose, CA (US)

(73) Assignee: APPLIED MATERIALS, INC., Santa Clara, CA (US)

(21) Appl. No.: 14/374,184

(22) PCT Filed: Jun. 1, 2012
(86) PCT No.: PCT/EP2012/060410

§ 371 Date: Feb. 3, 2015

(51) Int. Cl. C23C 14/35; C23C 14/14

(52) U.S. Cl. CPC C23C 14/352; C23C 14/14; C23C 14/35
USPC 204/192.13; 204/192.12; 204/192.15

(57) ABSTRACT

A method of depositing a layer of a material on a substrate is described. The method includes igniting a plasma of a sputter target for material deposition while the substrate is not exposed to the plasma, maintaining the plasma at least until exposure of the substrate to the plasma for deposition of the material on the substrate, exposing the substrate to the plasma by moving at least one of the plasma and the substrate, and depositing the material on the substrate, wherein the substrate is positioned for a static deposition process.

### TECHNICAL FIELD OF THE INVENTION

Embodiments of the present invention relate to layer deposition by sputtering from a target. Embodiments of the present invention particularly relate to sputtering layers on large area substrates, more particularly for static deposition processes. Embodiments relate specifically to a method of depositing a layer of a material on a substrate.

### BACKGROUND OF THE INVENTION

In many applications, it is necessary to deposit thin layers on a substrate, e.g. on a glass substrate. Typically, the substrates are coated in different chambers of a coating apparatus. Typically, the substrates are coated in a vacuum, using a vapor deposition technique.

Several methods are known for depositing a material on a substrate. For instance, substrates may be coated by a physical vapor deposition (PVD) process, a chemical vapor deposition (CVD) process or a plasma enhanced chemical vapor deposition (PECVD) process etc. Typically, the process is performed in a process apparatus or process chamber where the substrate to be coated is located. A deposition material is provided in the apparatus. A plurality of materials, but also oxides, nitrides or carbides thereof, may be used for deposition on a substrate. Coated materials may be used in several applications and in several technical fields. For instance, substrates for displays are often coated by a physical vapor deposition (PVD) process. Further applications include insulating panels, organic light emitting diode (OLED) panels, substrates with TFT, color filters or the like.

For a PVD process, the deposition material can be present in the solid phase in a target. By bombarding the target with energetic particles, atoms of the target material, i.e. the material to be deposited, are ejected from the target. The atoms of the target material are deposited on the substrate to be coated. In a PVD process, the sputter material, i.e. the material to be deposited on the substrate, may be arranged in different ways. For instance, the target may be made from the material to be deposited or may have a backing element on which the material to be deposited is fixed. The target including the material to be deposited is supported or fixed in a predefined position in a deposition chamber. In the case where a rotatable target is used, the target is connected to a rotating shaft or a connecting element connecting the shaft and the target.

Typically, sputtering can be conducted as magnetron sputtering, wherein a magnet assembly is utilized to confine the plasma for improved sputtering conditions. Thereby, the plasma confinement can also be utilized for adjusting the participle distribution of the material to be deposited on the substrate. The plasma distribution, the plasma characteristics and other deposition parameters need to be controlled in order to obtain a desired layer deposition on the substrate. For example, a uniform layer with desired layer properties is desired. This is particularly important for large area deposition, e.g. for manufacturing displays on large area substrates. Further, uniformity and process stability can be particularly difficult to achieve for static deposition processes, wherein the substrate is not moved continuously through a deposition zone. Accordingly, considering the increasing demands for the manufacturing of opto-electronic devices and other devices on a large scale, process uniformity and/or stability needs to be further improved.

### SUMMARY OF THE INVENTION

In light of the above, a method for depositing a layer of a material on a substrate according to independent claim 1 or 2 are provided. Further aspects, advantages, and features of the present invention are apparent from the dependent claims, the description and the accompanying drawings.

According to one embodiment a method of depositing a layer of a material on a substrate is provided. The method includes igniting a plasma of a sputter target for material deposition with a first magnet assembly position such that the substrate is not exposed to the plasma, and moving the magnet assembly in a second magnet assembly position whilst maintaining the plasma, wherein the second magnet assembly position results in the deposition of the material on the substrate.

According to another embodiment, a method of depositing a layer of a material on a substrate is provided, The method includes igniting a plasma of a sputter target for material deposition while the substrate is not exposed to the plasma, maintaining the plasma at least until exposure of the substrate to the plasma for deposition of the material on the substrate, wherein the exposure is provided at least by moving the substrate into a deposition area, and depositing the material on the substrate in the deposition area, wherein the substrate is positioned for a static deposition process.

According to yet another embodiment, a method of depositing a layer of a material on a substrate is provided. The method includes igniting a plasma of a sputter target for material deposition while the substrate is not exposed to the plasma, maintaining the plasma at least until exposure of the substrate to the plasma for deposition of the material on the substrate, exposing the substrate to the plasma by moving at least one of the plasma and the substrate, and depositing the material on the substrate, wherein the substrate is positioned for a static deposition process.

According to a second embodiment, a method of depositing a layer of a material on a substrate is provided. The method includes igniting a plasma of a sputter target for material deposition while the substrate is not exposed to the plasma, maintaining the plasma at least until exposure of the substrate to the plasma for deposition of the material on the substrate, exposing the substrate to the plasma by moving at least one of the plasma and the substrate, and depositing the material on the substrate wherein the igniting is conducted with a first magnet assembly position such that the first magnet assembly position results in a deposition of the material on a component arranged outside of a deposition area. The method further includes moving the magnet assembly in a second magnet assembly position whilst the maintaining the plasma, wherein the second magnet assembly position results in the deposition of the material on the substrate. This second embodiment can also be combined with additional or alternative aspects, details, and implementations of other embodiments described herein.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a deposition system illustrating sputtering according to embodiments described herein;

FIG. 2 shows another deposition system illustrating sputtering according to embodiments described herein;

FIG. 3 shows a deposition system illustrating yet further sputtering methods according to embodiments described herein;

FIG. 4 shows a flow chart illustrating a method of depositing a layer of a material on a substrate according to embodiments described herein;

FIG. 5 shows a flow chart illustrating another method of depositing a layer of a material on a substrate according to embodiments described herein;

FIG. 6 shows a flow chart illustrating a yet further method of depositing a layer of a material on a substrate according to embodiments described herein;

FIG. 7 shows a flow chart illustrating a yet further method of depositing a layer of a material on a substrate according to embodiments described herein; and

FIG. 8 shows a yet further deposition system illustrating sputtering methods according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

Embodiments described herein relate to methods of depositing a layer of a material on a substrate. Particularly for reactive sputtering processes, plasma stability is a critical parameter to be considered. Reactive sputtering processes, for example deposition processes during which a material is sputtered under oxygen atmosphere in order to deposit a layer containing an oxide of the sputtered material, need to be controlled with respect to plasma stability. Typically, a reactive deposition process has a hysteresis curve. The reactive deposition process can be, for example, a deposition of aluminum oxide (Al2O3) or silicon oxide (SiO2), wherein aluminum or silicon is sputtered from a cathode while oxygen is provided in the plasma. Thereby, aluminum oxide or silicon oxide can be deposited on a substrate. The hysteresis curve typically is a function of deposition parameters such as the voltage provided to the sputter cathode in dependence of the flow of a process gas, such as oxygen.

For a low process gas flow a comparably high cathode voltage is provided and the deposition process is conducted in a metallic mode. Even though a high deposition rate can be provided in the metallic mode, typically an absorbing layer is deposited, which is not appropriate for a plurality of applications. For higher process gas flow rates the deposition process turns into a poisoned mode, e.g. an oxygen mode wherein for example a transparent silicon oxide layer can be deposited. Yet, the deposition rate is comparably low and might not be beneficial for all applications. Accordingly, controlling the reactive deposition process might be conducted in a transition mode, where a transparent layer, such as silicon oxide, can be deposited at the comparably high rate. The above examples show that a stabilization of the plasma for certain deposition conditions might be required in order to provide a stable deposition process.

According to embodiments described herein, methods include igniting a plasma of a sputter target for material deposition while the substrate is not exposed to the plasma. Thereafter, the plasma is maintained at least until exposure of the substrate to the plasma for deposition of the material on the substrate. Thereby, the substrate is exposed to the plasma by moving at least one of the plasma and the substrate in order to deposit the material on the substrate. Accordingly, during a stabilization time period, the substrate is not exposed to the plasma for layer deposition. The substrate is then exposed after stabilization, wherein the plasma needs to be maintained. This is particularly beneficial for deposition processes wherein the substrate is positioned for a static deposition process.

Accordingly, embodiments described herein can prevent a substrate to be processes to be exposed to a plasma, for which arcing and/or spitting does occur. Thereby, process parameters for substrate processing, particularly for layer deposition, which are inferior due to unstabilized conditions, can be avoided for manufacturing of devices. The exposure of the substrate, i.e. the substrate for manufacturing devices, to stabilized process conditions results in better deposition properties as compared to layer deposition, wherein arcing and/or spitting is conducted and the respective plasma is directed towards the substrate.

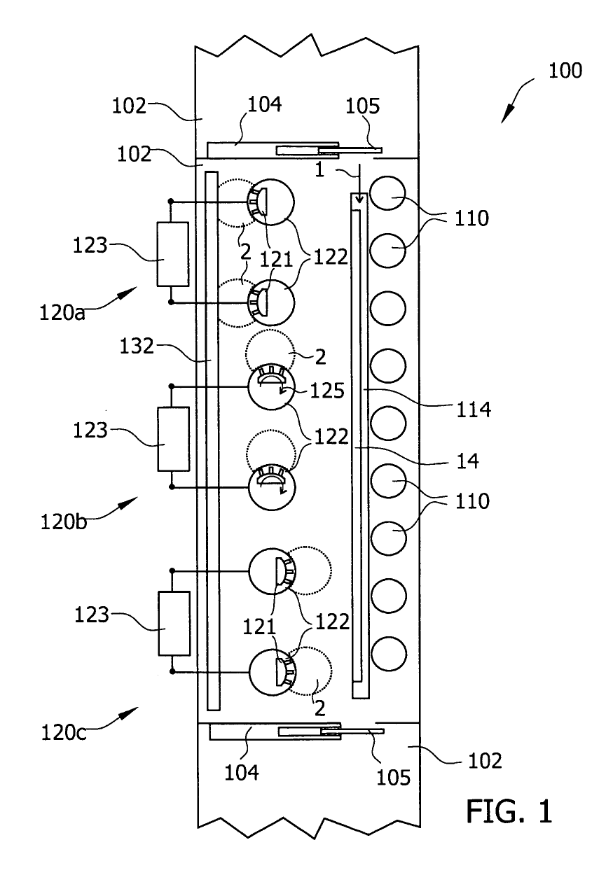

FIG. 1 shows a deposition apparatus 100. Exemplarily, one vacuum chamber 102 for deposition of layers therein is shown. As indicated in FIG. 1, further chambers 102 can be provided adjacent to the chamber 102. The vacuum chamber 102 can be separated from adjacent chambers by, a valve having a valve housing 104 and a valve unit 105. Thereby, after the carrier 114 with the substrate 14 thereon is, as indicated by arrow 1, inserted in the vacuum chamber 102, the valve unit 105 can be closed. Accordingly, the atmosphere in the vacuum chambers 102 can be individually controlled by generating a technical vacuum, for example, with vacuum pumps connected to the chamber 102, and/or by inserting process gases in the deposition region in the chamber.

According to typical embodiments, process gases can include inert gases such as argon and/or reactive gases such as oxygen, nitrogen, hydrogen and ammonia (NH3), Ozone (O3), activated gases or the like.

Within the chamber 102, rollers 110 are provided in order to transport the carrier 114, having the substrate 14 thereon, into and out of the chamber 102. The term “substrate” as used herein shall embrace both inflexible substrates, e.g., a glass substrate, a wafer, slices of transparent crystal such as sapphire or the like, or a glass plate, and flexible substrates, such as a web or a foil.

As illustrated in FIG. 1, within the chamber 102, deposition sources 122 are provided. The deposition sources can for example be rotatable cathodes having targets of the material to be deposited on the substrate. Typically, the cathodes can be rotatable cathodes with a magnet assembly 121 therein. Thereby, magnetron sputtering can be conducted for depositing of the layers. According to some embodiments, which can be combined with other embodiments described herein, cathodes 122 are connected to an AC power supply 123 such that the cathodes can be biased in an alternating manner.

As used herein, “magnetron sputtering” refers to sputtering performed using a magnetron, i.e. a magnet assembly, that is, a unit capable of generating a magnetic field. Typically, such a magnet assembly consists of one or more permanent magnets. These permanent magnets are typically arranged within a rotatable target or coupled to a planar target in a manner such that the free electrons are trapped within the generated magnetic field generated below the rotatable target surface. Such a magnet assembly may also be arranged coupled to a planar cathode. According to typical implementations, magnetron sputtering can be realized by a double magnetron cathode, i.e. cathodes 122, such as, but not limited to, a TwinMag™ cathode assembly. Particularly, for MF sputtering (middle frequency sputtering) from a target, target assemblies including double cathodes can be applied. According to typical embodiments, the cathodes in a deposition chamber may be interchangeable. Accordingly, the targets are changed after the material to be sputtered has been consumed. According to embodiments herein, middle frequency is a frequency in the range of 0.5 kHz to 350 kHz, for example, 10 kHz to 50 kHz.

According to different embodiments, which can be combined with other embodiments described herein, sputtering can be conducted as DC sputtering, MF (middle frequency) sputtering, as RF sputtering, or as pulse sputtering. As described herein, some deposition processes might beneficially apply MF, DC or pulsed sputtering. However, other sputtering methods can also be applied.

FIG. 1 shows a plurality of cathodes 122 with a magnet assembly 121 or magnetron provided in the cathodes. According to some embodiments, which can be combined with other embodiments described herein, the sputtering according to the described embodiments, can be conducted with one cathode or one pair of cathodes. However, particularly for applications for large area deposition, an array of cathodes or cathode pairs can be provided. Thereby, two or more cathodes or cathode pairs, e.g. three, four, five, six or even more cathodes or cathode pairs can be provided. Thereby, the array can be provided in one vacuum chamber. Further, an array can typically be defined such that adjacent cathodes or cathode pairs influence each other, e.g. by having interacting plasma confinement.

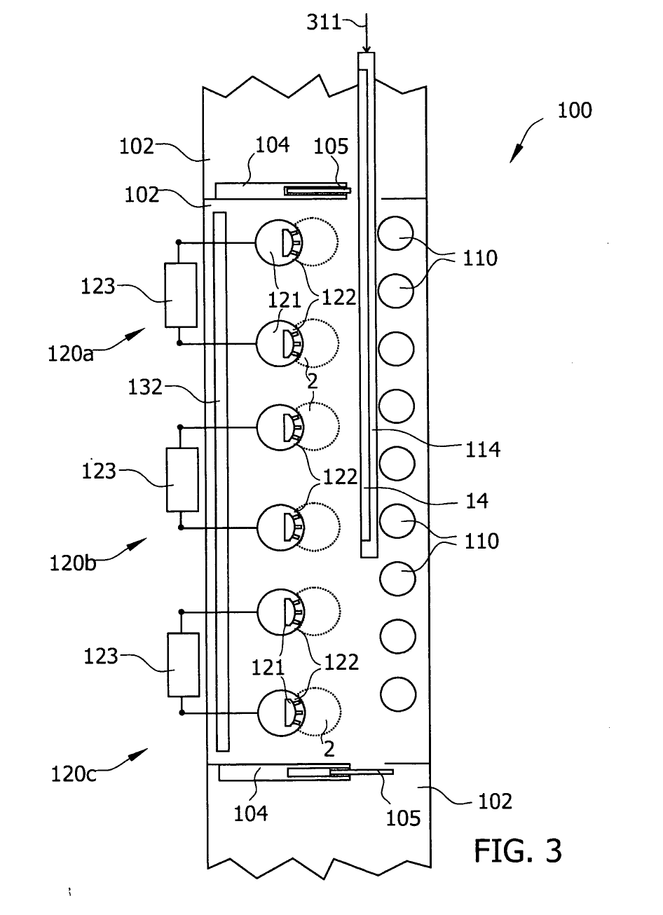

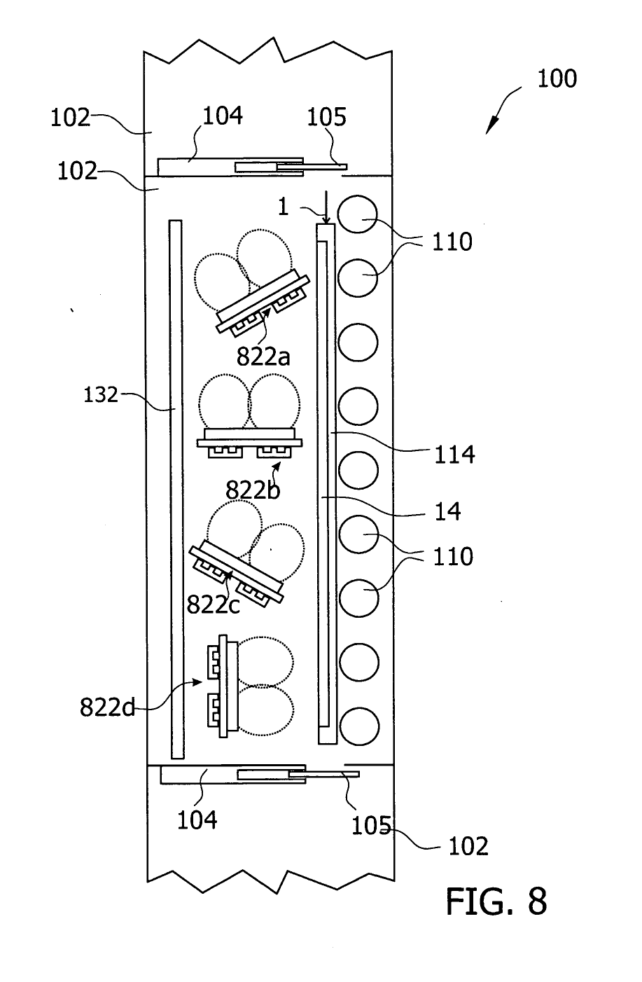

For rotatable cathodes, the magnet assemblies can be provided within a backing tube or with the target material tube. For planar cathodes the magnet can be provided on a side of the backing plate opposing the target material (see, e.g., FIG. 8). FIG. 1 shows 3 pairs of cathodes, each providing a deposition source 120a, 120b, and 120c respectively. The pair of cathodes have an AC power supply, e.g. for MF sputtering, RF sputtering or the like. Particularly for large area deposition processes and for deposition processes on an industrial scale, MF sputtering can be conducted in order to provide desired deposition rates. The magnet assemblies 121 or magnetrons shown in FIG. 1 have different rotational positions with respect to each other. This is mainly for illustration purposes in order to more easily explain the embodiments described herein. Typically, as shown in FIG. 3, the magnet assemblies of the cathodes in one chamber can have essentially the same rotational positions or can at least all be directed towards the substrate 14 or a corresponding deposition area. Typically, the deposition area is an area or region with a deposition system, which is provided and/or arranged for the depositing (the intended deposition) of the material on a substrate. The first deposition source 120a has magnet assemblies facing away from the substrate and/or the respective deposition area. Accordingly, the plasma 2 is also confined facing away from the substrate 14 and is directed to a shield 132, which can collect material to be sputtered while the plasma is directed towards the shield. As indicated by arrow 125 (see deposition source 120b), the magnet assemblies 121 of the deposition source 120b are rotated around their axes and towards the substrate 14 and a respective deposition area. Accordingly, also the plasmas 2 are rotated. The magnet assemblies 121 and correspondingly the plasmas 2, as shown for deposition source 120c, have been further rotated to expose the substrate 14 to the plasma and the material to be deposited.

Accordingly, as exemplarily shown for source 120a, the substrate is at the beginning not exposed to the plasma 2. This condition of non-exposure can be maintained until the plasma 2 is stabilized. The magnet assemblies and correspondingly the plasma can then be rotated, as exemplarily shown for source 120b, towards the substrate while the plasma is maintained. Accordingly, the stabilized plasma is maintained until exposure of the substrate 14, as exemplarily shown for source 120c.

According to embodiments described herein, which can be combined with other embodiments described herein, the ignited plasma and the substrate are moved relative to each other. Accordingly, an exposure of the substrate to the plasma and the corresponding material deposition is provided after stabilization of the plasma.

A movement of the magnet assembly and/or a deposition source has been used, e.g. for pre-sputtering and/or target conditioning. Pre-sputtering and target conditioning can be utilized in addition to the methods described herein. However, such pre-sputtering and/or target conditioning is different from the embodiments described herein. For pre-sputtering and/or target conditioning, the magnet assemblies are moved, e.g. to a position as shown for source 120a. The plasma is ignited for pre-sputtering and/or target conditioning. Thereafter, the plasma is switched off. Thereafter, the magnet assemblies are rotated towards the substrate. That is the rotation shown for source 120b is conducted without the plasma 2, i.e. different as compared to FIG. 1. After the magnet assembly is positioned as shown for source 120c, the plasma is ignited again and stabilizes while the substrate is exposed to the plasma.

It is to be understood that the different plasma positions for sources 120a, 120b and 120c are used in FIG. 1 for illustration purposes. Typically, all deposition sources in one chamber or for one deposition area will face away from the substrate or the corresponding deposition area for plasma ignition, will be rotated towards the deposition area while the plasma is maintained, and will expose the substrate to the stabilized plasma. Yet, according to different embodiments, which can be combined with other embodiments described herein, the plasma sources in one chamber can have varying plasma positions (rotational positions for rotary cathodes) during the deposition of the layer on the substrate. For example, the magnet assemblies or magnetrons can be moved relative to each other and/or relative to the substrate, e.g. in an oscillating or back-and-forth manner, in order to increase the uniformity of the layer to be deposited.

According to some embodiments, which can be combined with other embodiments described herein, the embodiments described herein can be utilized for Display PVD, i.e. sputter deposition on large area substrates for the display market. According to some embodiments, large area substrates or respective carriers, wherein the carriers have a plurality of substrates, may have a size of at least 0.67 m². Typically, the size can be about 0.67 m2 (0.73×0.92 m—Gen 4.5) to about 8 m² to about 8 m², more typically about 2 m² to about 9 m² or even up to 12 m². Typically, the substrates or carriers, for which the structures, apparatuses, such as cathode assemblies, and methods according to embodiments described herein are provided, are large area substrates as described herein. For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

The embodiments described herein allow for maintaining the stability of a reactive process, e.g. at the correct point of the hysteresis curve, without exposing a substrate to the initial process stabilization deposition, which could create deleterious effects for device performance and/or post-processing.

According to some embodiments, which can be combined with other embodiments described herein, the sputter deposition process is conducted in metallic mode or in a transition mode. Thereby, arcing for a pre-stabilized plasma or other plasma conditions, which do not correspond to the desired plasma conditions for deposition after stabilization, are more likely to occur as compared to a poisoned reactive sputtering mode, i.e. a mode where an excess amount of reactive processing gas is provided.

According to yet further embodiments, which can be combined with other embodiments described herein, the target material can be selected from the group consisting of: aluminum, silicon, tantalum, molybdenum, niobium, titanium and copper. Particularly, the target material can be selected from the group consisting of aluminum and silicon. The reactive sputter processes provide typically deposited oxides of these target materials. However, nitrides or oxi-nitrides might be deposited as well.

According to a yet further typical embodiment, sputter deposition of Al₂0₃ may be beneficially realized by the embodiments describe herein. For example, sputter deposition of Al₂0₃ can be utilized in realizing cost effective integration of metal oxide semiconductors (e.g. IGZO, ZnOx, etc.) as the active material in TFT backplanes for Display. In light of the fact that reactive sputtering of Al₂0₃ is difficult due to the process stabilization time and potential contamination on the substrate during this stabilization time, the non-exposure of the substrate during the stabilization period and the exposure of the substrate with only the stabilized plasma can be beneficial.

According to embodiments described herein, the methods provide a sputter deposition for a positioning of the substrate for a static deposition process. Typically, particularly for large area substrate processing, such as processing of vertically oriented large area substrates, it can be distinguished between static deposition and dynamic deposition. A dynamic sputtering, i.e. an inline process where the substrate moves continuously or quasi-continuously adjacent to the deposition source, would be easier due to the fact the process can be stabilized prior to the substrates moving into a deposition area, and then held constant as substrates pass by the deposition source. Yet, a dynamic deposition can have other disadvantages, e.g. particle generation. This might particularly apply for TFT backplane deposition. According to embodiments described herein a static sputtering can be provided, e.g. for TFT processing, wherein the plasma can be stabilized prior to deposition on the pristine substrate. Thereby, it should be noted that the term static deposition process, which is different as compared to dynamic deposition processes, does not exclude any movement of the substrate as would be appreciated by a skilled person. A static deposition process can include, for example, a static substrate position during deposition, an oscillating substrate position during deposition, an average substrate position that is essentially constant during deposition, a dithering substrate position during deposition, a wobbling substrate position during deposition, a deposition process for which the cathodes provided in one chamber, i.e. a predetermined set of cathodes provided in the chamber, a substrate position wherein the deposition chamber has a sealed atmosphere with respect to neighboring chambers, e.g. by closing valve units separating the chamber from an adjacent chamber, during deposition of the layer, or a combination thereof. Accordingly, a static deposition process can be understood as a deposition process with a static position, a deposition process with an essentially static position, or a deposition process with a partially static position of the substrate. Thereby, a static deposition process, as described herein, can be clearly distinguished from a dynamic deposition process without the necessity that the substrate position for the static deposition process is fully without any movement during deposition.

As shown in FIG. 1, embodiments described herein can be provided for a static deposition process, e.g. valve units 105 are closed during deposition, with a plurality of rotary cathodes, e.g. two or more rotary cathodes. While deposition process is switched off, the substrate 14 is moved into the position for deposition in the deposition area. The process pressure can be stabilized. The cathodes 122 are powered while the magnet assemblies 121 are rearward (as e.g. shown for source 120a) toward the pre-sputter shields 132. Once the process is stabilized, the cathode magnet assemblies 121 are rotated (as shown for source 120b) toward the front to deposit the correct stoichiometry of the material to be deposited onto the static substrate until end of deposition. For example, this can be the correct stoichiometry for AlxOy deposition.

According to yet further embodiments, which can be combined with other embodiments described herein, film uniformity might be even further improved if the cathode magnet assemblies are rotated back toward the pre-sputter shields in the same direction (see arrow 125) as before at the end of the film deposition. Thereby, the plasma exits on the opposite side of the target from whence it came, thus providing symmetry and uniform film thickness. This can be particularly useful for thinner films where symmetry and/or uniformity is more critical.

As shown in FIG. 1 for some films, such as Al2O3, AC power supplies 123 such as MF power supplies can be provided. In such a case, the cathodes do not require additional anodes, which can e.g. be removed, as a complete circuit including cathode and anode is provided by a pair of cathodes 122.

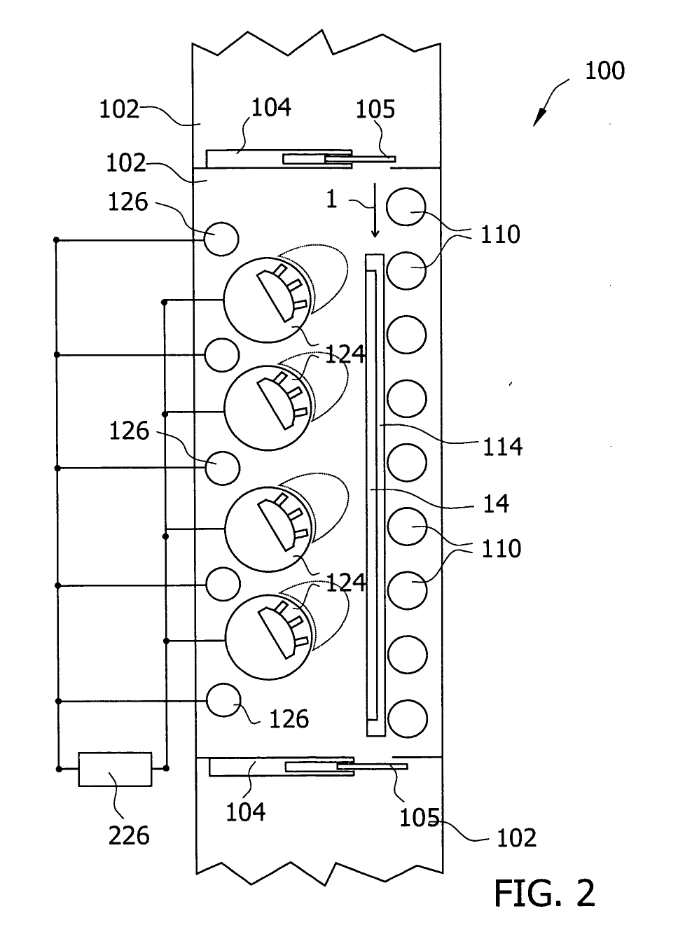

As shown in FIG. 2, methods described herein can also be provided for other sputter deposition processes. FIG. 2 shows cathodes 124 and anodes 126, which are electrically connected to DC power supply 226. As compared to FIG. 1, FIG. 2 shows all cathodes being rotated simultaneously towards the substrate for exposure thereof after the plasma is stabilized. Sputtering from a target for e.g. a transparent conductive oxide film is typically conducted as DC sputtering. The cathodes 124 are connected to the DC power supply 226 together with anodes 126 for collecting electrons during sputtering. According to yet further embodiments, which can be combined with other embodiments described herein, one or more of the cathodes can each have their corresponding, individual voltage supply. Thereby, one power supply can be provided per cathode for at least one, some or all of the cathodes. Accordingly, at least a first cathode can be connected to a first power supply, and a second cathode can be connected to a second power supply. According to yet further embodiments, which can be combined with other embodiments described herein, for example, materials like ITO, IZO, IGZO or MoN, which might also benefit from the non-exposure of the substrate during a stabilization period might be deposited with a DC sputter deposition process.

According to different embodiments described herein, a sputtering process can be provided, wherein the exposure of the substrate to the plasma is conducted after plasma exposure. The plasma stabilization can be particularly useful for sputtering processes having a hysteresis curve, e.g. reactive sputtering processes. As shown exemplarily in FIGS. 1 and 2, the process can be conducted with rotary cathodes and a rotating magnet assembly, i.e. a rotating magnet yoke therein. Thereby, a rotation around the longitudinal axis of the rotary cathode is conducted.

FIG. 3 illustrates yet another embodiment. FIG. 3 is similar to FIG. 1 with the differences explained below. The deposition of the material on the substrate 14 is conducted in a deposition area. The plasma 2 is ignited with a position of the magnet assembly 121 or magnetron resulting in material flow towards the deposition area. After stabilization of the plasma the substrate is moved in the deposition area while the plasma for the deposition of the material on the substrate is maintained. As shown in FIG. 3, the lower valve unit 105 is closed while the substrate 14, e.g. provided on a carrier 114 is moved into the chamber while the plasma is ignited. The movement is indicated by arrow 311 in FIG. 3. Accordingly, as shown in FIG. 3, the upper valve unit 105 is in an open position such that the substrate 14 can be inserted in the chamber 102.

The open position of the upper valve unit 105 results in the fact that the chamber 102 having the cathodes 122 therein is open towards the adjacent chamber 102, which can be another deposition chamber, a load lock chamber or the like. Accordingly, the chamber with the deposition area therein is not isolated from the other chambers and it is more difficult to maintain stable atmospheric conditions. That is, due to the open valve unit the degree of vacuum and the partial pressures of processing gas are more difficult to control. Yet, it is possible to move the substrate into a position for a static deposition process as described above after the plasma is stabilized. Further, thereafter the upper valve unit 105 in FIG. 3 can be closed for deposition. After deposition or towards the end of the film deposition, the lower valve unit 105 can be opened and the substrate can be removed from the chamber 102. Thereby, in the event the plasma is still switched on while the substrate is moved out of the position for a static deposition process, the different portions of the substrate (the upper and lower portion in the cross-section shown in FIG. 3) are exposed to the substrate for a similar time. Accordingly, film uniformity can be improved by removing the substrate 14 from the chamber 102 while the cathodes are switched on.

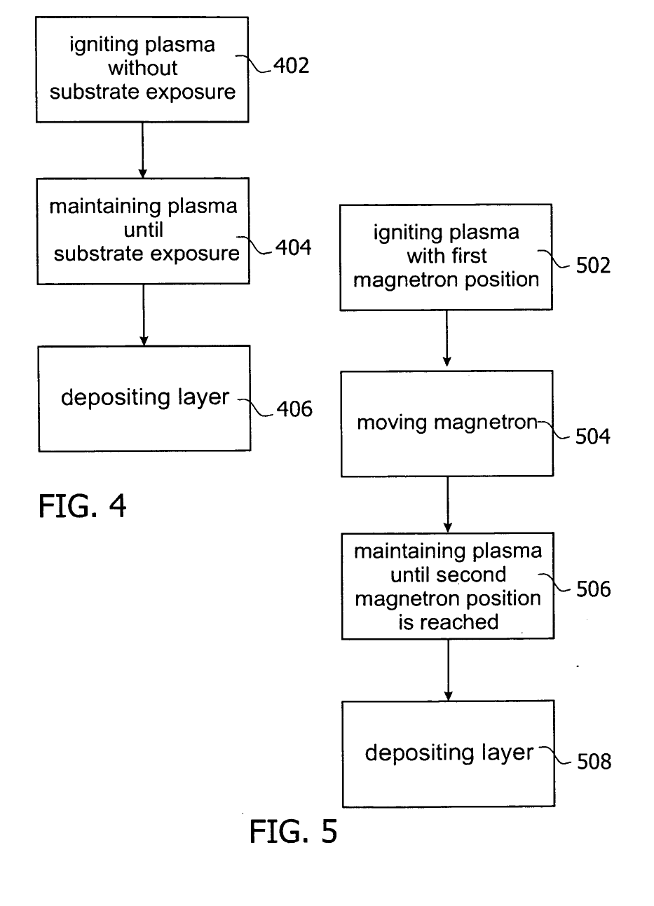

An embodiment of a method of depositing a layer of a material on a substrate is shown in FIG. 4. In step 402 a plasma of a sputter target for material deposition is ignited while the substrate is not exposed to the plasma. In step 404 the plasma is maintained at least until exposure of the substrate to the plasma for deposition of the material on the substrate. Thereby, the substrate is exposed to the plasma by moving at least one of the plasma and the substrate. In step 406 the material is deposited on the substrate, wherein the substrate is positioned for a static deposition process. Typically, the material of the target can be deposited in the form of an oxide, a nitride, or an oxi-nitride of the target material, i.e. with a reactive sputtering process.

According to yet further typical embodiments, which can be combined with other embodiments described herein, the cathode can be a rotary cathode and the target can be a rotary target with a magnet assembly disposed therein. Thereby, magnetron sputtering can be conducted. In order to expose the substrate to the plasma after stabilization of the plasma, a method as illustrated by the flow chart shown in FIG. 5 can be conducted. Thereby, in step 502 the igniting of the plasma is conducted with a first magnet position. The first magnet position results in a deposition of the material on a component arranged outside of a deposition area. For example, the component can be a pre-sputter shield, a portion of a vacuum chamber, or the like. In step 504 the magnet assembly or magnetron is moved in a second magnet position. In step 506 the plasma is maintained until a second magnet position is reached, which results in the deposition of the material on the substrate. Thereafter, in step 508, the film is deposited on the substrate. Movement of the magnet assembly relative to the substrate, which is provided in a chamber, corresponds to the embodiments described with respect to FIGS. 1, 2 and 8.

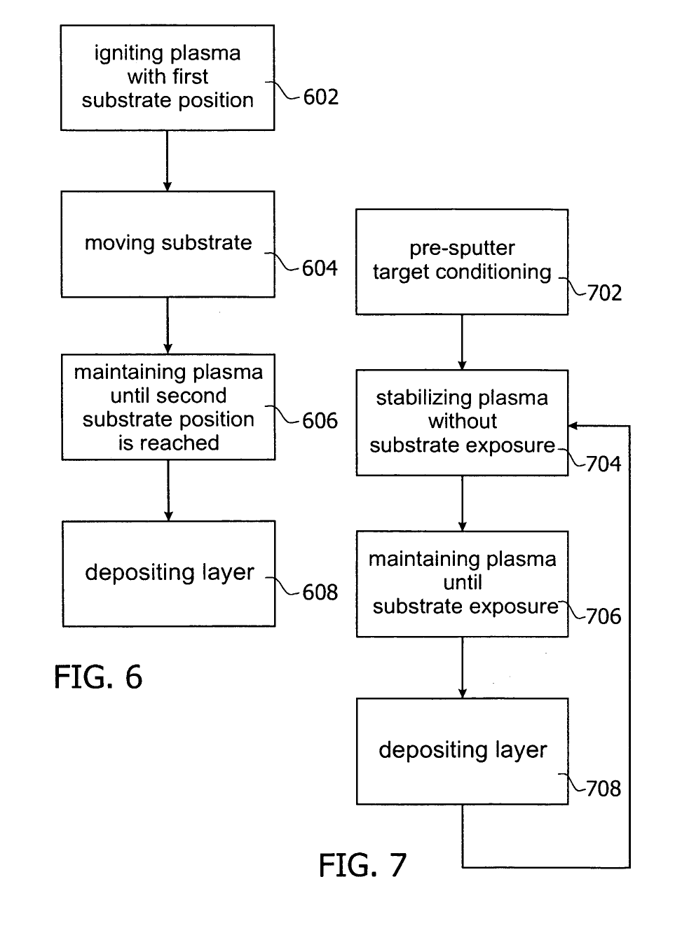

However, as described above, it is also possible that the substrate is moved relative to the plasma. As shown in FIG. 6, the plasma can be ignited in step 602 while the substrate is in a first substrate position. Thereafter, the substrate can be moved in the deposition area in step 604. The plasma is maintained until the deposition position for the static deposition process is reached in step 606. Thereafter, the layer is deposited with a static deposition process in step 608. Thereby, as described above in more detail, according to typical embodiments, which can be combined with other embodiments described herein, the positioning of the substrate for the static deposition process can include a static substrate position during deposition, an oscillating substrate position during deposition, an average substrate position that is essentially constant during deposition, or a combinations thereof.

A yet further method, which can be combined with other embodiments described herein, is described with respect to the flow chart shown in FIG. 7. Therein, in step 702, a target conditioning is conducted. The target conditioning can result in removal of contamination or oxidation from a target which has not been used previously or which has not been used for some time. This can be done by having the magnet assembly being directed to a pre-sputter shield, another system component, a dummy substrate, or the like. Accordingly, the material deposition during pre-sputtering is not conducted on a substrate having a device to be manufactured thereon. After pre-sputtering, the plasma can be switched off or can be maintained. A substrate for material deposition therein can be provided in a deposition area. Thereafter, the plasma can be stabilized for the subsequent steps 704 to 706. In step 704 the plasma of a sputter target for material deposition is stabilized while the substrate is not exposed to the plasma. For the first repetition of steps 704 to 708, the stabilization can also be conducted during the pre-sputtering. In step 706 the plasma is maintained at least until exposure of the substrate to the plasma for deposition of the material on the substrate. Thereby, the substrate is exposed to the plasma by moving at least one of the plasma and the substrate. In step 708 the material is deposited on the substrate, wherein the substrate is positioned for a static deposition process. The sequence of steps 704 to 708 can be repeated at least once or several times as indicated in FIG. 7. Accordingly, FIG. 7 shows a process similar to the embodiments described with respect to FIGS. 4 to 6, wherein an additional pre-sputter step 702 is provided.

FIG. 8 shows a deposition apparatus 100 for illustrating yet further embodiments described herein. Exemplarily, one vacuum chamber 102 for deposition of layers therein is shown. Embodiments described with respect to FIG. 8 can be combined with other embodiments described herein, and particularly corresponds to FIG. 1.

As illustrated in FIG. 8, within the chamber 102, deposition sources 822a to 822d are provided. Contrary to FIG. 1, the deposition sources shown in FIG. 8 are planar cathodes having targets of the material to be deposited on the substrate. Thereby, a backing plate can be provided. The planar targets are provided on one side of the backing plate and one or more magnet assemblies can be provided on the opposing side of the backing plate. As shown in FIG. 8, two magnet assemblies can be provided for a cathode. However, also one or more than two magnet assemblies can be provided. Thereby, magnetron sputtering can be conducted for depositing of the layers.

Within FIG. 8 one cathode is shown for each of the deposition sources 822a to 822d. However, according to typical implementations, magnetron sputtering can be realized by a double magnetron cathode, such as, but not limited to, a TwinMag™ cathode assembly. Particularly, for MF sputtering (middle frequency sputtering) from a target, target assemblies including double cathodes can be applied. According to typical embodiments, the cathodes in a deposition chamber may be interchangeable. Accordingly, the targets are changed after the material to be sputtered has been consumed. According to embodiments herein, middle frequency for planar and/or rotatable cathodes can, e.g. be a frequency in the range of 5 kHz to 100 kHz, for example, 10 kHz to 50 kHz.

FIG. 8 shows a four cathodes 822a to 822d, respectively having magnet assemblies. The cathodes 822a to 822d shown in FIG. 8 have different rotational positions with respect to each other and with respect to the substrate 14. This is mainly for illustration purposes in order to more easily explain the embodiments described herein. Typically, as shown in FIG. 3, the planar cathodes and, thus, magnet assemblies of the cathodes in one chamber can have essentially the same rotational positions or can at least all be directed towards the substrate 14 or a corresponding deposition area. The first deposition source 822a is facing away from the substrate and/or the respective deposition area. Accordingly, the plasma 2 is also confined facing away from the substrate 14 and is directed to a shield 132, which can collect material to be sputtered while the plasma is directed towards the shield. As indicated by deposition sources 822b and 822c, respectively, the deposition source can be rotated towards the substrate 14 and a respective deposition area. Accordingly, also the plasmas 2 are rotated. The cathodes and correspondingly the plasmas 2 as shown for deposition sources 822c and 822d have been further rotated to expose the substrate 14 to the plasma and the material to be deposited.

Accordingly, as exemplarily shown for sources 822a and 822b, the substrate is not exposed to the plasma 2 at the beginning. This condition of non-exposure can be maintained until the plasma 2 is stabilized. The magnet assemblies and correspondingly the plasma can then be rotated, as exemplarily shown for sources 822b and 822c, towards the substrate while the plasma is maintained. Accordingly, the stabilized plasma is maintained until exposure of the substrate 14, as exemplarily shown for sources 822c and 822d. Thus, as shown in FIG. 8, in the event of planar cathodes, the rotational position of the magnet assemblies can be provided by a rotation of the cathode itself. Different therefrom, the embodiments described with respect to FIGS. 1 and 2, where a target rotation is already provided for having a rotary cathode, a rotation of the magnet assembly can be provided within the cathode for rotary targets.

According to embodiments described herein, which can be combined with other embodiments described herein, the ignited plasma and the substrate are moved relative to each other. Accordingly, an exposure of the substrate to the plasma and the corresponding material deposition is provided after stabilization of the plasma. According to yet further embodiments, which can be combined with other embodiments described herein, a substrate movement 311 shown in FIG. 3 can also be provided for planar cathodes.

As described herein, according to some embodiments, the plasma of a rotary cathode or a planar cathode is maintained before the exposure of the substrate until arcing at the target is reduced below a predetermined threshold. Typically, the plasma can be maintained before deposition for process stabilization for a time period of at least 1 s or above, particularly for 5 s to 10 s.

According to yet further embodiments, which can be combined with other embodiments described herein, the plasma is maintained before the exposure of the substrate to the plasma until a measured value is reduced below a predetermined threshold or increased above a predetermined threshold. Thereby, for example, the measured value can be at least one value selected from the group consisting of: a value indicative of arcing, a power supply stabilization value, a power supply voltage level, a power supply current level, a partial pressure value of a gas, an output value of a monitoring device such as a plasma emission monitor (PEM), a time-based value, and combinations thereof.

While the foregoing is directed to embodiments of the invention, other and further embodiments of the invention may be devised without departing from the basic scope thereof, and the scope thereof is determined by the claims that follow.

1. A method of depositing a layer of a material on a substrate, the method comprising:
igniting a plasma of a sputter target for material deposition with a first magnet assembly position such that the substrate is not exposed to the plasma; and
moving the magnet assembly in a second magnet assembly position whilst maintaining the plasma, wherein the second magnet assembly position results in the deposition of the material on the substrate.

2. A method of depositing a layer of a material on a substrate, the method comprising:
igniting a plasma of a sputter target for material deposition while the substrate is not exposed to the plasma;
maintaining the plasma at least until exposure of the substrate to the plasma for deposition of the material on the substrate, wherein the exposure is provided at least by moving the substrate into a deposition area; and
depositing the material on the substrate in the deposition area, wherein the substrate is positioned for a static deposition process.

3. The method according to claim 2, wherein the positioning of the substrate for the static deposition process includes: a static substrate position during deposition, an oscillating substrate position during deposition, an average substrate position that is essentially constant during deposition, a dithering substrate position during deposition, a wobbling substrate position during deposition, or a combination thereof.

4. The method according to claim 1, wherein the plasma is maintained before the exposure of the substrate until a measured value is reduced below a predetermined threshold or increased above a predetermined threshold.

5. The method according to claim 1, further comprising: flowing a processing gas such that the deposition of the material is a reactive deposition process.

6. The method according to claim 5, wherein the deposition process is conducted metallic mode or in transition mode.

7. The method according to claim 1, wherein the target material is selected from the group consisting of: aluminum, silicon, tantalum, molybdenum, niobium, titanium, and copper, particularly from the group consisting of aluminum and silicon.

8. The method according to claim 1, further comprising: moving the magnet assembly in a third magnet assembly position along the same direction as the moving from the first position to the second position whilst the maintaining the plasma, wherein the third magnet assembly position results in deposition of the material on a component arranged outside of the deposition area.

9. The method according to claim 1, wherein the plasma is maintained before deposition for process stabilization for a time period of 1 s or above.

10. The method according to claim 1, wherein the sputter targets are rotary sputter targets.

11. The method according to claim 10, wherein the moving of the magnet assembly is conducted by rotation of the magnet assembly inside the rotary sputter target.

12. The method according to claim 1, wherein the moving of the magnet assembly is conducted by rotation of the cathode including the magnet assembly.

13. The method according to claim 1, comprising at least a pair of sputter targets, wherein the sputter target is at least one target of the pair of sputter targets.

14. The method according to claim 2, wherein the plasma is maintained before the exposure of the substrate until a measured value is reduced below a predetermined threshold or increased above a predetermined threshold.

15. The method according to claim 3, wherein the plasma is maintained before the exposure of the substrate until a measured value is reduced below a predetermined threshold or increased above a predetermined threshold.

16. The method according to claim 2, further comprising: flowing a processing gas such that the deposition of the material is a reactive deposition process.

17. The method according to claim 9, wherein the deposition process is conducted in metallic mode or in transition mode.

18. The method according to claim 11, wherein the target material is selected from the group consisting of aluminum and silicon.

19. The method according to claim 14, wherein the plasma is maintained before deposition for process stabilization for a time period of 5 s to 10 s.

20. The method according to claim 13, wherein the pair of sputter targets is operated by applying a middle frequency voltage in a range of 0.5 kHz to 350 kHz between the pair of sputter targets.
